(19) United States
(12) Patent Application Publication
(10) Pub. No.: US 2008/0012059 A1
(43) Pub. Date: Jan. 17, 2008

(54) Semiconductor device and manufacturing method thereof

(75) Inventor: Eiji Hasunuma, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/822,803

(22) Filed: Jul. 10, 2007

(30) Foreign Application Priority Data
Jul. 11, 2006 (JP) 2006-190044

(51) Int. Cl. H01L 27/108; H01L 21/8242

(52) U.S. Cl. 257/309; 438/253; 257/E21.013; 257/E21.646

(57) ABSTRACT

In a semiconductor device having a concave-type capacitor, HSG silicon is formed on a side surface of a lower electrode while no HSG silicon is formed on a bottom of the lower electrode.

This application claims priority to prior Japanese patent application JP2006-190044, the disclosure of which is incorporated herein by reference.

### BACKGROUND OF THE INVENTION

1. Field of the Invention

The present invention relates to a semiconductor device and a manufacturing method thereof, and more particularly to a semiconductor device having a concave-type capacitor and a manufacturing method thereof.

2. Description of the Related Art

Recently, semiconductor devices have increasingly been required to be scaled up. A dynamic random access memory (DRAM) having a memory capacity of 1 Gbit has been put into practical use. Generally, a DRAM memory cell is formed by one transistor and one capacitor. The amount of charge stored in the capacitor is used as memory information. The charge of the capacitor is supplied and removed by the transistor. The capacitor has two electrodes including a storage node electrode (lower electrode) connected to a diffusion layer electrode of the transistor and a reference potential electrode (upper electrode) connected in common. The capacitor also has a capacitor insulation film between these electrodes.

As memory cells in large-capacity memories have become smaller in size, spaces required for capacitors have also been reduced. In a DRAM, however, the amount of charge in a capacitor is used as memory information. Therefore, at least a certain capacitance value is required to achieve stable operation of the memory. Reduction of the thickness of a capacitor insulating film (dielectric film), application of a high-dielectric film to a capacitor insulating film, enhancement of a surface area of a capacitor electrode, and the like may be required to maintain at least a certain capacitance value in a small-sized memory cell. Basically, for this purpose, use is made of two methods including reducing the thickness of a dielectric film and increasing a surface area of a capacitor electrode. The method of reducing the thickness of a dielectric film is performed by further reduction of the thickness of a conventional dielectric film or application of a new material having a high dielectric constant. For example, use is made of tantalum pentoxide (Ta₂O₅) which is an insulating film having a dielectric constant higher than that of a silicon oxide film (SiO₂) or a silicon nitride film (Si₃N₄).

There may be two methods to increase a surface area of an electrode: One method includes increasing an aspect ratio of a concave forming an electrode in order to increase a surface area of a capacitor. Another method includes using a rough silicon film or a hemispherical grain (HSG) silicon film having hemispherical projecting particles. Provision of irregularities on a surface of an electrode can increase about twice its surface area. Formation of a concave having a high aspect ratio, provision of HSG on a surface of an electrode, and application of a high-dielectric film are combined to maintain a desired capacitance value.

An HSG silicon film is formed as follows: An amorphous silicon film is formed as a lower electrode of a capacitor. Heat treatment is performed on the formed amorphous silicon film in an atmosphere of SiH₄ (monosilane) or Si₂H₆ (disilane) to form cores of an HSG silicon film. Furthermore, heat treatment is performed in a high vacuum to form hemispherical grains. During transition in crystallization of silicon atoms to which the cores have previously been attached, the heat treatment causes migration of the silicon atoms so as to grow hemispherical crystal grains.

In this event, if the amorphous silicon contains a large amount of phosphorus (P) as an impurity, for example, the migration of the silicon atoms is inhibited so that sufficient growth of HSGs is not achieved. Accordingly, an HSG treatment is generally performed with an impurity concentration not more than about 1×10²⁰ to 2×10²⁰ atoms·cm⁻³ to thereby promote the growth of HSGs. Then, when the impurity concentration is electrically insufficient, heat treatment is performed again, for example, in an atmosphere of PH₃ (phosphine). Thus, phosphorus (P) is introduced into the silicon film so as to increase an impurity concentration.

The following patent documents relate to a DRAM memory cell using an HSG silicon film. Japanese laid-open patent publication No. 11-214661 (Patent Document 1) and Japanese laid-open patent publication No. 11-145419 (Patent Document 2) disclose methods of manufacturing a crown-shaped capacitor. Patent Document 1 discloses forming a first amorphous silicon film, a second doped amorphous silicon film, and a third amorphous silicon film to uniformize the size of HSG silicon and prevent depletion of an HSG silicon film. Patent Document 2 discloses controlling an etching depth with an endpoint marker layer when a storage electrode is formed by etching. These patent documents are focused on a crown-shaped capacitor, which is structurally different from the present invention. Accordingly, these patent documents are lack of recognition to the aforementioned problems, which are to be resolved by the present invention. These patent documents fail to teach or suggest the structure or manufacturing method of the present invention.

### SUMMARY OF THE INVENTION

Memory cells are reduced in size and made finer according to enhancement of the capacity of DRAMs. In order to maintain a capacitance value of a capacitor in a fine memory cell, an HSG treatment is performed on a capacitor electrode to thereby increase a surface area of the memory cell. However, as memory cells are made much finer, new problems become evident in an HSG treatment. These problems will be described with reference to FIGS. 1 to 7, which are cross-sectional views showing an outline of a manufacturing process of a concave-type capacitor.

As shown in FIG. 1, a contact interlayer insulating film 1 is deposited on a semiconductor substrate (not shown). Although not shown in FIG. 1, a transistor and a diffusion layer are formed on the semiconductor substrate. Then, a contact pattern is patterned by the use of a photoresist, and a contact hole C1 is formed by dry etching. Next, a doped polysilicon film for a plug material is embedded into the contact hole C1. Dry etch-back or chemical mechanical polishing (CMP) is carried out so as to form a contact plug 11 (FIG. 2). The contact plug 11 is connected to a diffusion layer of a cell transistor (not shown).

Subsequently, a cylinder interlayer insulating film 2 is deposited on the semiconductor substrate. Patterning is performed by the use of a photoresist. A storage node hole C2 is then formed by dry etching (FIG. 3). The storage node hole C2 has a concave shape with a high aspect ratio. The size of the bottom of the storage node hole C2 is smaller than that of an opening portion of the storage node hole C2 on an upper surface of the cylinder interlayer dielectric film 2. Then, a doped polysilicon film 12 and a non-doped amorphous silicon film 13, which are to be a lower electrode of a capacitor, are deposited on the semiconductor substrate (FIG. 4). The lower electrode of the capacitor serves as a storage node electrode in a DRAM memory cell.

Next, a photoresist is embedded into the storage node hole C2. A portion of the doped polysilicon film 12 and the non-doped amorphous silicon film 13 that has not been covered with the photoresist is removed from the surface of the cylinder interlayer dielectric film 2 by dry etch-back. The storage node electrode is insulated and separated from other storage node electrodes. The storage node electrode is formed only within the storage node hole C2 in the cylinder interlayer insulating film 2 (FIG. 5). In this manner, the electrode of the capacitor is formed concavely in the cylinder interlayer dielectric film 2. Accordingly, this capacitor is referred to as a concave-type capacitor or a cylinder-type capacitor.

Subsequently, an HSG treatment is performed on the non-doped amorphous silicon film 13 in order to increase a capacitance value of the capacitor. Thus, an HSG silicon film 14 is formed as shown in FIG. 6. In this event, if particles 14 of the HSG silicon have a large particle diameter, particles of the HSG silicon on the bottom of the storage node hole C2 are brought into contact with particles of the HSG silicon on side surfaces of the storage node hole C2 as shown in an encircled portion of FIG. 7. This contact causes clogging of a space near the bottom of the storage node hole C2. In the following description, the particles of the HSG silicon are simply referred to as HSG silicon.

As the bottom of the storage node electrode has a smaller size, the space near the bottom is more likely to be clogged by the HSG silicon. The contact of the HSG silicon causes reduction of a surface area of the electrode and restricts an increase of a capacitance value of the capacitor. Furthermore, a deposition gas is insufficiently supplied to the clogged portion so as to cause non-uniform deposition of a capacitor insulating film. Thus, the film thickness of the capacitor insulating film is smaller at some local portions. As a result, a capacitor leakage current is problematically produced at the portions of the capacitor insulating film having a small film thickness.

It is therefore an object of the present invention to prevent a capacitor leakage current in a concave-type capacitor from being produced by contact between HSG silicon on a bottom of a storage node electrode and HSG silicon on a side surface of the storage node electrode. According to the present invention, a bottom of a storage node electrode is prevented from being clogged by HSG silicon on the bottom of the storage node electrode and HSG silicon on a side surface of the storage node electrode. The film thickness of a capacitor insulating film is made uniform. The reliability of the capacitor insulating film is improved.

That is, another object of the present invention is to provide a semiconductor device with high reliability and a method of manufacturing such a semiconductor device.

In order to resolve the above problems, the present invention basically adopts the following technology. As a matter of course, the present invention covers applied technology in which various changes and modifications are made therein without departing from the spirit of the present invention.

A semiconductor device according to the present invention has a concave-type capacitor. HSG silicon is formed on a side surface of a lower electrode while no HSG silicon is formed on a bottom of the lower electrode.

In the semiconductor device according to the present invention, the bottom of the lower electrode may be formed by a contact pad provided on a contact plug and on an interlayer insulating film.

In the semiconductor device according to the present invention, the bottom of the lower electrode may be smaller than the contact pad and be located inside of the contact pad.

In the semiconductor device according to the present invention, the contact pad may be connected to the contact plug connected to a diffusion layer and be formed by the same conductive material as the contact plug.

In the semiconductor device according to the present invention, the contact pad may be formed of doped polysilicon.

A method of manufacturing a semiconductor device according to the present invention includes a step of forming a first interlayer insulating film on a semiconductor substrate and forming a contact hole in the first interlayer insulating film, a step of depositing a conductive film so as to fill the contact hole with the conductive film and forming a contact plug and a contact pad, a step of depositing a second interlayer insulating film and forming a storage node hole extending to the contact pad, a step of depositing a layer including at least non-doped amorphous silicon as a lower electrode of a capacitor and forming the lower electrode of the capacitor by dry etch-back, a step of attaching a core onto a surface of the non-doped amorphous silicon and performing an HSG treatment so that no HSG silicon is formed on a bottom of the lower electrode, and a step of forming a capacitor insulating film and an upper electrode of the capacitor.

In the method of manufacturing a semiconductor device according to the present invention, doped polysilicon may be deposited as an underlayer of the non-doped amorphous silicon for the lower electrode of the capacitor.

In the method of manufacturing a semiconductor device according to the present invention, the forming step of the lower electrode by dry etch-back may include etching and removing the doped polysilicon and the non-doped amorphous silicon from a bottom of the storage node hole so as to expose a portion of a surface of the contact pad.

In a method of manufacturing a semiconductor device according to the present invention, no HSG silicon is grown on a bottom of a storage node electrode in a concave-type capacitor. Accordingly, HSG silicon on a side surface of the storage node electrode is not brought into contact with HSG silicon on the bottom of the storage node electrode. Thus, no clogging is caused in the storage node electrode. Elimination of clogging in the storage node electrode allows a capacitor insulating film to have a uniform film thickness. The reliability of the capacitor insulating film is improved. As a result, it is possible to obtain a semiconductor device with high reliability and a method of manufacturing such a semiconductor device.

The above and other objects, features, and advantages of the present invention will be apparent from the following description when taken in conjunction with the accompanying drawings which illustrate preferred embodiments of the present invention by way of example.

### BRIEF DESCRIPTION OF THE DRAWINGS

FIG. 1 is a cross-sectional view showing an outline of a related manufacturing process of a concave-type capacitor;

FIG. 2 is a cross-sectional view showing an outline of the related manufacturing process of the concave-type capacitor;

FIG. 3 is a cross-sectional view showing an outline of the related manufacturing process of the concave-type capacitor;

FIG. 4 is a cross-sectional view showing an outline of the related manufacturing process of the concave-type capacitor;

FIG. 5 is a cross-sectional view showing an outline of the related manufacturing process of the concave-type capacitor;

FIG. 6 is a cross-sectional view showing an outline of the related manufacturing process of the concave-type capacitor;

FIG. 7 is a cross-sectional view showing an outline of the related manufacturing process of the concave-type capacitor;

FIG. 8 is a cross-sectional view showing an outline of a manufacturing process of a concave-type capacitor according to the present invention;

FIG. 9 is a cross-sectional view showing an outline of the manufacturing process of the concave-type capacitor according to the present invention;

FIG. 10 is a cross-sectional view showing an outline of the manufacturing process of the concave-type capacitor according to the present invention;

FIG. 11 is a cross-sectional view showing an outline of the manufacturing process of the concave-type capacitor according to the present invention;

FIG. 12 is a cross-sectional view showing an outline of the manufacturing process of the concave-type capacitor according to the present invention;

FIG. 13 is a cross-sectional view showing an outline of the manufacturing process of the concave-type capacitor according to the present invention; and

FIG. 14 is a cross-sectional view showing an outline of the manufacturing process of the concave-type capacitor according to the present invention.

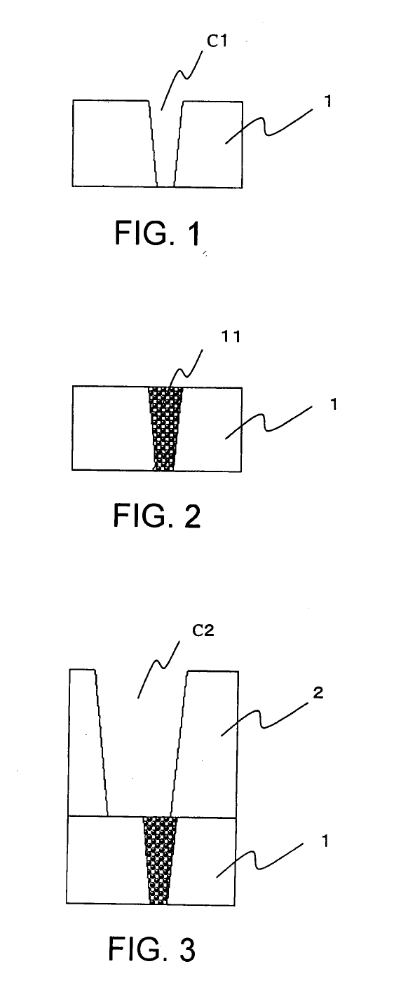

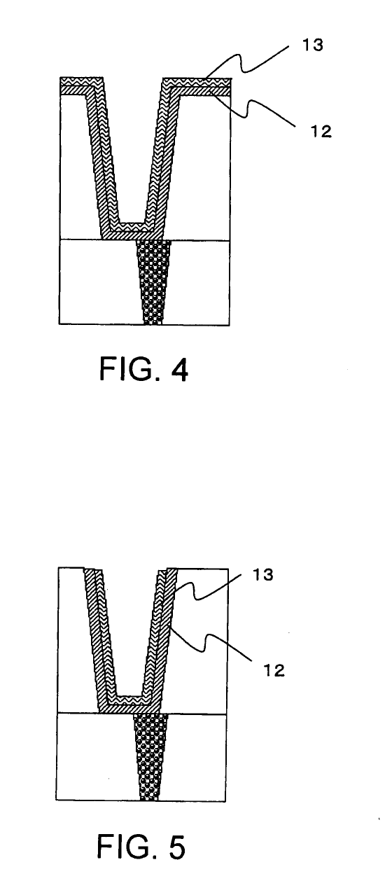

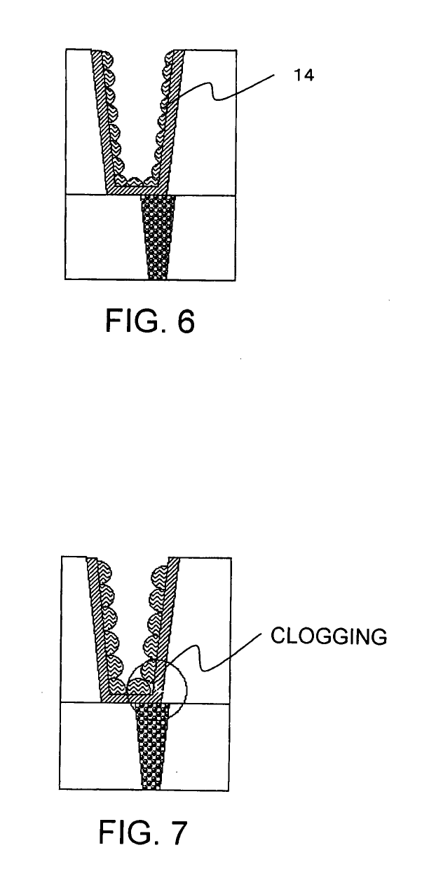

### DETAILED DESCRIPTION OF THE PREFERRED EMBODIMENTS

A semiconductor device and a manufacturing method thereof according to the present invention will be described below with reference to the drawings.

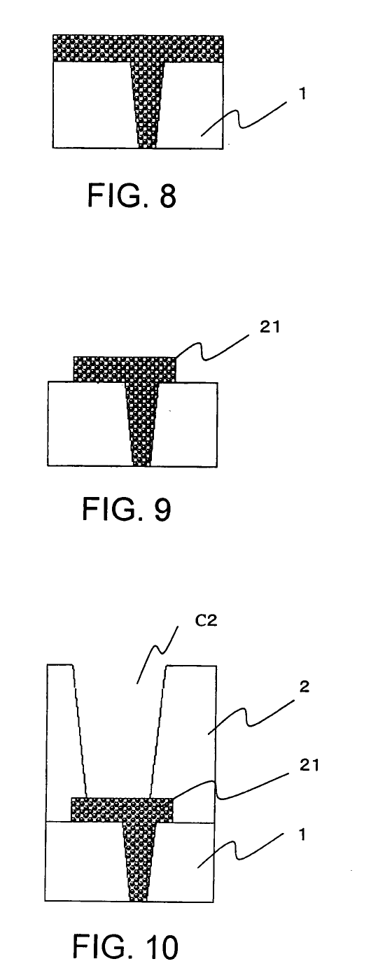

An embodiment will be described with reference to FIGS. 8 to 14, which are cross-sectional views showing an outline of a manufacturing process of a concave-type capacitor in the first example.

As shown in FIG. 8, a contact hole is formed in a contact interlayer insulating film 1. Then, a conductive material of a doped polysilicon film is embedded as a pad material into the contact hole. The conductive material is flattened by CMP, and a contact pad is patterned by the use of a photoresist. Subsequently, a contact pad 21 is formed by dry etching. The contact pad 21 includes a contact plug portion connected to a diffusion layer (not shown) of a cell transistor and a contact pad portion on an upper surface of the contact interlayer insulating film 1. The contact pad portion of the contact pad 21 is formed so as to fully cover the contact plug portion (FIG. 9).

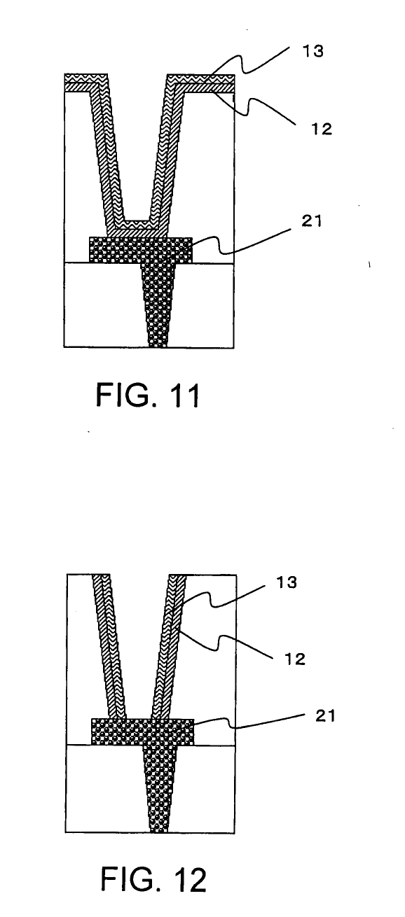

Next, a cylinder interlayer insulating film 2 is deposited on the contact interlayer insulating film 1, and a photoresist is patterned to define an area in which a storage node is to be formed. Then, a storage node hole C2 having a concave shape is formed in the cylinder interlayer insulating film 2 by dry etching (FIG. 10). The size of a bottom of the storage node hole C2 is smaller than that of the contact pad 21. The storage node hole C2 is formed so that the bottom of the storage node hole C2 is located inside of the contact pad 21. Accordingly, it is desirable that the center of the storage node hole C2 be approximately aligned with the center of the contact pad 21. Subsequently, a doped polysilicon film 12 and a non-doped amorphous silicon film 13, which are to be a storage node electrode, are deposited as shown in FIG. 11.

Next, the doped polysilicon film 12 and the non-doped amorphous silicon film 13 are etched by anisotropic dry etch-back so as to form a storage node electrode separated from other storage node electrodes. This process etches a portion of the doped polysilicon film 12 and the non-doped amorphous silicon film 13 located on an upper surface of the cylinder interlayer dielectric film 2 and on a surface of the contact pad 21. Thus, the doped polysilicon film 12 and the non-doped amorphous silicon film 13 are left only on side surfaces of the storage node hole C2. Accordingly, the contact pad 21 is located on the bottom of the concave-type storage node electrode while the doped polysilicon film 12 and the non-doped amorphous silicon film 13 are located on the side surfaces of the concave-type storage node electrode (FIG. 12).

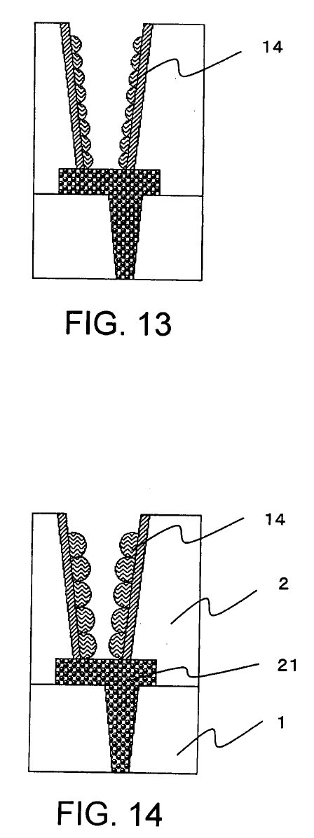

Next, a HSG treatment is performed on the non-doped amorphous silicon film 13 in order to increase the capacitance value of the capacitor. In this event, HSG silicon does not grow on the bottom of the storage node electrode because the pad material of the doped polysilicon is exposed on the bottom of the storage node electrode. Only the non-doped amorphous silicon film 13 located on the side surfaces of the storage node hole C is selectively subjected to the HSG treatment and thus converted into HSG silicon 14 (FIG. 13). Even if the HSG silicon is further enlarged to increase a capacitance value of the capacitor, the bottom of the storage node electrode is not clogged by the HSG silicon because no HSG silicon grows on the bottom of the storage node electrode. Accordingly, the particle diameter of the HSG silicon can be increased without causing the bottom of the storage node electrode to be clogged by the HSG silicon. A surface area of the capacitor electrode can be increased with the large HSG silicon (FIG. 14).

After the formation of the storage node electrode, a capacitor insulating film is formed. Since the bottom of the storage node electrode is not clogged by the HSG silicon, a gas for deposition of the capacitor insulating film can be introduced uniformly into the storage node electrode. Consequently, the capacitor insulating film can be deposited with a uniform film thickness. Furthermore, a conductive film is deposited so as to face the storage node electrode, and patterning is carried out so as to form a counter electrode opposed to the storage node electrode. The counter electrode is connected to a reference potential of the memory cell of the DRAM. Thus, the capacitor according to the present invention is formed between the storage node electrode connected to the diffusion layer of the cell transistor in the memory cell and the counter electrode connected to the reference potential.

In a capacitor according to the present invention, a hole for electrodes is formed in a cylinder interlayer insulating film. A storage node electrode (lower electrode), a capacitor insulating film, and a counter electrode (upper electrode) are formed within the hole. Although the above description relates to a DRAM memory cell, the present invention is not limited to a DRAM. For example, the present invention is applicable to any general-purpose capacitor having a lower electrode and an upper electrode that correspond to the aforementioned storage node electrode and counter electrode, respectively.

As described above, a contact pad structure of doped polysilicon is provided on a bottom of a lower electrode of a concave-type capacitor. As a consequence, a HSG treatment is performed only on side surfaces of the lower electrode while no HSG treatment is performed on the bottom of the lower electrode. Since no HSG treatment is performed on the bottom of the lower electrode, the film thickness of a capacitor insulating film can be made uniform, and a capacitor leakage current can be prevented. Therefore, with high reliability of the capacitor insulating film having no variations in film thickness, it is possible to obtain a semiconductor device with high reliability and a method of manufacturing such a semiconductor device.

Although the present invention has been specifically described based on the illustrated example, the present invention is not limited to the illustrated example. It should be understood that various changes and modifications may be made therein without departing from the spirit of the present invention and are thus included in the scope of the present invention.

What is claimed is:

1. A semiconductor device having a concave-type capacitor, wherein:
HSG silicon is formed on a side surface of a lower electrode while no HSG silicon is formed on a bottom of the lower electrode.

2. The semiconductor device according to claim 1, wherein:
the bottom of the lower electrode is formed by a contact pad provided on a contact plug and on an interlayer insulating film.

3. The semiconductor device according to claim 2, wherein:
the bottom of the lower electrode is smaller than the contact pad and is located inside the contact pad.

4. The semiconductor device according to claim 3, wherein:
the contact pad is connected to the contact plug connected to a diffusion layer and is formed by the same conductive material as the contact plug.

5. The semiconductor device according to claim 4, wherein:
the contact pad is formed of doped polysilicon.

6. A method of manufacturing a semiconductor device, comprising the steps of:
forming a first interlayer insulating film on a semiconductor substrate;
forming a contact hole in the first interlayer insulating film;
depositing a conductive film so as to fill the contact hole with the conductive film;
forming a contact plug and a contact pad;
depositing a second interlayer insulating film;
forming a storage node hole extending to the contact pad;
depositing a layer including at least non-doped amorphous silicon as a lower electrode of a capacitor;
forming the lower electrode of the capacitor by dry etch-back;
attaching a core onto a surface of the non-doped amorphous silicon;
performing an HSG treatment so that no HSG silicon is formed on a bottom of the lower electrode; and
forming a capacitor insulating film and an upper electrode of the capacitor.

7. The method according to claim 6, wherein:
doped polysilicon is deposited as an underlayer of the non-doped amorphous silicon for the lower electrode of the capacitor.

8. The method according to claim 7, wherein:
the forming step of the lower electrode by dry etch-back comprises etching and removing the doped polysilicon and the non-doped amorphous silicon from a bottom of the storage node hole so as to expose a portion of a surface of the contact pad.
